(19) United States
(12) Patent Application Publication
(10) Pub. No.: US 2013/0163627 A1
(43) Pub. Date: Jun. 27, 2013

(54) Laser Illuminator System

(71) Applicants: Jean F. Seurin, Princeton Junction, NJ (US); Chuni L. Ghosh, West Windsor, NJ (US); Qing Wang, Plainsboro, NJ (US)

(72) Inventors: Jean F. Seurin, Princeton Junction, NJ (US); Chuni L. Ghosh, West Windsor, NJ (US); Qing Wang, Plainsboro, NJ (US)

(73) Assignee: PRINCETON OPTRONICS, Mercerville, NJ (US)

(21) Appl. No.: 13/337,098

(22) Filed: Dec. 24, 2011

(51) Int. Cl. H01S 3/04; H01S 3/00; H01S 5/183; H01S 5/42

(52) U.S. Cl. 372/36; 372/50.124; 372/38.02

(57) ABSTRACT

An optical illuminator using Vertical Cavity Surface Emitting Laser (VCSEL) is disclosed. Optical modules configured using single VCSEL and VCSEL arrays bonded to a thermal submount to conduct heat away from the VCSEL array, are suited for high power and high speed operation. High speed optical modules are configured using single VCSEL or VCSEL arrays connected to a high speed electronic module on a common thermal submount or on a common Printed Circuit Board (PCB) platform including transmission lines. The electronic module provides low inductance current drive and control functions to operate the VCSEL and VCSEL array. VCSEL apertures are designed for a desired beam shape. Additional beam shaping elements are provided for VCSELs or VCSEL arrays, for desired output beam shapes and/or emission patterns. VCSEL arrays may be operated in continuous wave (CW) or pulse operation modes in a programmable fashion using a built-in or an external controller.

### BACKGROUND OF THE INVENTION

1. Field of the Invention

This invention relates to the field of laser illumination and in particular, to an illuminator system including single Vertical Cavity Surface Emitting Laser (VCSEL) and arrays of VCSELs.

2. Description of the Related Arts

Laser illumination sources have diverse applications depending upon different operating modes such as, continuous wave (CW), Quasi Continuous Wave (QCW) or pulsed operation. To name just a few, laser illumination is widely used in the field of surveillance imaging, recording images of objects moving at high speed, gesture recognition, time of flight illumination for three dimensional (3D) imaging, etc. Currently, laser devices operating in the visible as well as in the Infra-red (IR) region of the electromagnetic spectrum are readily available. However, current cost of devices is rather high for other emerging applications particularly in consumer electronics and optics and/or in portable devices. Few key developments that would make laser illumination sources more attractive and affordable for emerging applications are, availability of a speckle free illumination over large area, short and/or fast pulse illumination system, high speed and/or low impedance peripheral devices and connectors such as, driving electronics, high speed connectors, optical elements for beam shaping, and small foot print.

Specific applications of short optical pulses include but are not limited to, strobe light that can freeze a high speed movement of an object so that it can be recorded using a conventional slow speed camera or a radiation detector for digitally recording a single image or an entire scene. A sequence of short illumination pulses can be used for many other sensing applications such as tracking movement and 3D measurement using technologies such as structured light. Another example is the coding of illumination pulses to provide methods for discriminating between a coded illumination sequence and illumination effects from other nearby sources. Short optical pulse is also required for time of flight measurement between a source and an object for determining the depth or distance of the object.

For these types of applications, one basic requirement is a source of radiation at a specific wavelength (visible, IR, far IR etc.) which can be rapidly turned on and off to generate a short pulse or short pulse sequence of radiation. For illuminating a large scene for example, in a surveillance application, high energy pulse of radiation is required to be distributed uniformly over a large illuminating area. Short optical pulses having high pulse energy can be generated in Q-switched or mode-locked solid state lasers that are optically pumped. However Q-switched or mode-locked lasers have large footprint, require high electrical energy requirement for operation and elaborate cooling peripheral equipment.

Alternatively, semiconductor diode laser sources such as, edge emitting laser (EEL) and vertical cavity surface emitting laser (VCSEL) can be fabricated to work at various wavelengths and can generate high energy short output pulses in a very small footprint. Diode lasers can be operated at drive current that are relatively small as compared to pump current required to operate a Q-switched or a mode locked solid state laser. While EELs are currently used for many applications including short pulse generation for optical communication, VCSELs have several distinct advantages over the EELs that make them more suitable for optical illumination applications.

In general, VCSELs have faster rise and fall times and therefore are capable of producing very short pulses. One advantage of short pulses is that the wavelength chirp is small which helps in wavelength filtering and high speed detection. VCSELs also have a symmetric output radiation pattern which makes it much more adaptable to simple optical methods for generating or modifying, the output light for a desirable illumination pattern. For example, different beam shapes including but not limited to, a Gaussian, flat top or ring shape pattern may be generated by suitably designing a VCSEL's aperture or by using external beam shaping devices such as lenses, diffusers, etc. that can be used for a single VCSEL or arranged in an array to be used with a VCSEL array.

Another advantage of VCSELs is that many of them may be arranged in closely packed one or two dimensional arrays. VCSEL arrays, especially arrays of single mode VCSELs, are typically very high speed devices and can be operated with pulse duration of the order of nanoseconds or less, and rise times of sub-nanoseconds. When operated together, an array of VCSELs produce high energy pulses. Very compact high power VCSEL arrays facilitate minimizing electrical conductor lengths and reducing inductance. As a result it is more suitable for applying fast rise time high drive current pulses thereby facilitating generation of high energy short optical pulses from a VCSEL array. They can be operated at temperatures as high as about 100 deg C. in enclosed environments. Simple optical methods such as providing apertures may be used to shape either individual beam or the collective emission from the entire array for producing a desirable illumination pattern. VCSEL arrays with their large number of emitters do not exhibit speckle effect which are typically seen in the output from EELs or other types of lasers. Eliminating speckle greatly increases the resolution of the illuminated image.

For high speed operation of VCSEL it is important that a fast electrical drive current can be applied. For applying a high speed driving current it is essential that the parasitic elements are minimized while packaging VCSELs and VCSEL arrays. Furthermore, for high power operation of VCSEL, high thermal conductivity of the package is also important. It can be well appreciated that for VCSEL arrays to be operated at high speed and at high power of the order of several Watts for example, packaging of the device must incorporate both the requirements simultaneously. Different arrangements for mounting VCSELs either for individual operation or collective operation for high output power, are described in number of patent and non-patent publications. Contents of these publications to be described shortly are herein incorporated by reference in their entirety.

In the U.S. Pat. No. 6,888,169 issued to Malone et al. on May 3, 2005, a high speed subassembly for a single VCSEL device is described. More specifically, a multi-tier ceramic subassembly to house a VCSEL and/or a photodetector is described where one or more tiers of the subassembly includes metallic connector pads to wire bond at least one terminal of a VCSEL and/or a photodetector. The subassembly can further be connected to a printed circuit board to connect the VCSEL to a current driving circuit. It is noted that the electrical contacts are on only one side of the subassembly and do not provide a connection to the underside for direct surface mount attaching to a PCB. The subassembly is only suitable for single devices and not designed for VCSEL arrays. Furthermore, there is no provision in the design for thermal conduction of heat away from the VCSEL arrays particularly encountered in high power operation.

For assembling arrays of VCSELs a submount designed to be installed in a package, using a low capacitance material is described in the U.S. Pat. No. 6,741,626 issued to Lin et al. on May 25, 2004. More specifically, the submount consists of pads on one surface and the VCSEL device is bonded to one of the pads. The other connection is made by wire bonds from the VCSEL array to a second pad. And while the submount has high speed, it does not provide connections from the top surface to the underneath surface of the submount. It is not suited for high speed connection to a printed circuit board (PCB) and it does not support low thermal resistance path to a heat sink.

A different submount is described in U.S. Pat. No. 6,853,007 B2 issued to Tatum et al. on Feb. 8, 2005 where a submount includes electrical conducting via holes (vias hereinafter) between the top pads and bottom pads for providing electrical connections from the device to the bottom surface of the submount. Each pad contains only one via per pad and therefore does not provide sufficiently low thermal resistance path which is particularly needed for high current/power operation. In addition, the vias and pads do not provide a low inductance path which is necessary for driving the VCSEL at high current and high speed, in particular for a high power VCSEL array where a plurality of VCSELs operate together.

A submount for efficient thermal dissipation for high power VCSEL is described in the U.S. Pat. No. 6,888,871 issued to Zhang et al on May 3, 2005. The submount described therein is constructed from diamond or similar high thermal conductivity material and directly bonded to the VCSEL array; however there is no description of the electrical contacts for powering the VCSEL array and methods for making high speed electrical connections to the VCSEL array or to the submount.

In a United States Patent Application Publication No. 2005/0201443 by Riaziat et al. on Sep. 15, 2005, a TO5 packaging for single optoelectronic device is disclosed. The device is packaged on a printed circuit board (PCB) having high speed transmission lines to reduce parasitic elements for increasing the speed of the device. The TO5 package disclosed therein is adaptable for a laser/detector pair. However, the disclosure does not describe packing laser or detector arrays in that fashion.

In a United States Patent Application Publication No. 2011/0176567 A1 by J. Joseph on Jul. 21, 2011, a high power VCSEL array and a submount that provides operation at high speed and efficient heat dissipation for the array, are described. More specifically, the submount described therein comprises specially designed and fabricated VCSEL arrays with raised mesa structures and additional non emitting shorting mesas to provide the means for connecting to the high speed submount and proving heat sinking However, the submount is not electrically bonded to a high speed PCB including mechanically bonding to a heat sink for providing efficient cooling for high power operation.

In this invention a laser illuminator (or illuminator) system is disclosed. The illuminator comprises single VCSEL or VCSEL arrays arranged in a module that has high thermal conductivity and includes high speed electronics circuit such as a current driver. The parasitic elements of the driver circuit are reduced by low inductance sub-assembly design that is suitable for surface mounting to a PCB including high speed transmission lines to connect the VCSEL or VCSEL array to high speed driver electronics. The VCSEL arrays disclosed in this invention may be surface mounted directly to a heat sink or a heat sink region optionally included in the PCB, for rapid heat dissipation during high power operation. Furthermore, optical elements are provided for shaping the optical output beam or emission from the VCSEL—optical output may be modified for individual VCSEL elements or for the entire array.

### SUMMARY OF THE INVENTION

In one embodiment of invention an optical illuminator comprises an optical module and an electronic module mounted on a common platform having a high thermal conductivity. More specifically, the optical module includes a single VCSEL or VCSEL array(s) connected to the electronic module using high speed transmission lines collocated on a PCB. The PCB is mounted in a housing that provides high thermal conductivity for rapid heat dissipation from the VCSEL or VCSEL arrays. The electronic module provides drive current and control functions to the VCSEL array and can optionally be controlled using an external controller.

In different variant embodiments the illuminator disclosed in this invention may be configured in a modular fashion on a PCB to incorporate desired functionalities including high speed operation, high power operation, pulsed operation, continuous operation, or a desired combination thereof. The illuminator may be programmed to operate in different reconfigurable modes for a desired output power, a desired speed and a desired illumination/emission pattern.

In one embodiment of a high power illuminator, a VCSEL array is bonded to large area bonding pads located on one surface of a thermal submount. The thermal submount is constructed from a high thermal conductivity material such that heat generated in the VCSEL array is rapidly dissipated away to avoid thermal degradation during high power operation. In a variant embodiment the large area bonding pads are wrapped around respective edges of the thermal submount and connected to a second set of large area bonding pads located on an opposite surface underside of the thermal submount. The thermal submount is designed to be directly bonded to a heat sink, a PCB or a specially designed PCB including a heat sink region, such that the VCSEL array is in good thermal contact with a heat sink for rapid heat dissipation from the VCSEL array.

In an alternate embodiment, the thermal submount further includes a plurality of via holes located between a top surface and an opposing bottom surface of the submount. The via holes are coated and/or filled with a material that has a high thermal conductivity as well as a high electrical conductivity so as to provide good thermal and electrical contact between corresponding large bonding pads located on the opposing surfaces of the thermal submount. The thermal submount is designed to be directly bonded to a heat sink, a PCB or a specially designed PCB including a heat sink region, such that the VCSEL array is in good thermal contact with a heat sink for rapid heat dissipation from the VCSEL array.

In another embodiment of the invention a VCSEL array and an electronic circuit including at least one current driver circuit, is bonded on a common surface of a thermal submount. The electronic circuit may be mounted flip-chip so as to electrically connect the VCSEL array and the current driver circuit using a transmission line on the thermal submount. In an alternative configuration the electronic circuit is bonded on a different bonding pad in a conventional manner where the VCSEL array is electrically connected to the current driver circuit using wire or ribbon bonding. The thermal submount is surface bonded to a heat sink or alternatively, to a PCB. In one variation, the thermal submount including the VCSEL array and the electronic circuit, are encapsulated together with an optical component including one or more beam shaping elements.

In one embodiment, an illuminator is configured by bonding optical and electronic modules on a PCB having high speed transmission lines to electrically connect the optical module and an electronic module with optional impedance matching elements. The high speed connectors on the PCB may be interfaced to an external controller for operating and controlling the VCSEL arrays.

In a different embodiment, VCSEL is designed to emit light in a pre-determined pattern by a suitable current confining aperture structure. In other alternative embodiment, the optical an external optical component is used as a window to seal the VCSEL array and the electronic module on the PCB, wherein the optical component may further include one or more beam shaping elements for changing emission pattern from the VCSEL array. Beam shaping elements are placed at a distance from the VCSEL array such that a desired emission pattern may be achieved.

### BRIEF DESCRIPTION OF THE DRAWINGS

The accompanying drawings incorporating one or more aspects of the present invention in different figures form a part of the specification. The embodiments of the invention will be more clearly understood when the following detailed description is read in conjunction with the accompanying drawing figures in which:

FIG. 1 shows a single VCSEL module to illustrate basic principles incorporated in constructing an illuminator system according to this invention;

FIG. 2 shows a VCSEL array module to illustrate basic principles to configure an optical module for an illuminator system according to this invention;

FIG. 3 shows a wrap around bonding pads incorporated in configuring a VCSEL array optical module for an illuminator system;

FIG. 4 shows a VCSEL array disposed on a submount having a plurality of via holes for configuring an optical module for an illuminator system;

FIG. 5 shows a VCSEL array and an electronic module co-located on a submount to configure a high speed optical module for an illuminator system;

FIG. 6 shows VCSEL current confining aperture design and corresponding radial distribution of gain and optical emission profile as a function of current confining aperture diameter;

FIG. 7 shows VCSEL array including a beam shaping optical component for configuring an optical module for an illuminator system;

FIG. 8 shows a VCSEL array and a high speed electronic module on a common PCB platform for configuring a high speed module for an illuminator system;

FIG. 9 shows a VCSEL array and a high speed electronic module connected using high speed transmission line;

FIG. 10 shows a plurality of VCSEL arrays co-located on a common submount for creating larger VCSEL arrays; and

FIG. 11 shows an enclosed high power and high speed illuminator system including optical and electronic modules and high speed transmission line connectors on a common PCB platform.

### DETAILED DESCRIPTION OF THE INVENTION

For clarity and ease of discussion, each drawing figure shows a particular aspect or a combination of few aspects that may be implemented in an embodiment either alone or, in combination with one or more aspects shown in other embodiments. An element not shown in any particular embodiment is not be construed as precluded from the embodiment unless stated otherwise. Different aspects presented separately in the preferred embodiments are intended to provide a broader perspective of the invention. Different combinations and sub-combinations of various aspects that may occur to those skilled in the art, still fall within the broader framework of the detailed description of the invention presented in the following sections of the written description.

### Single VCSEL Module:

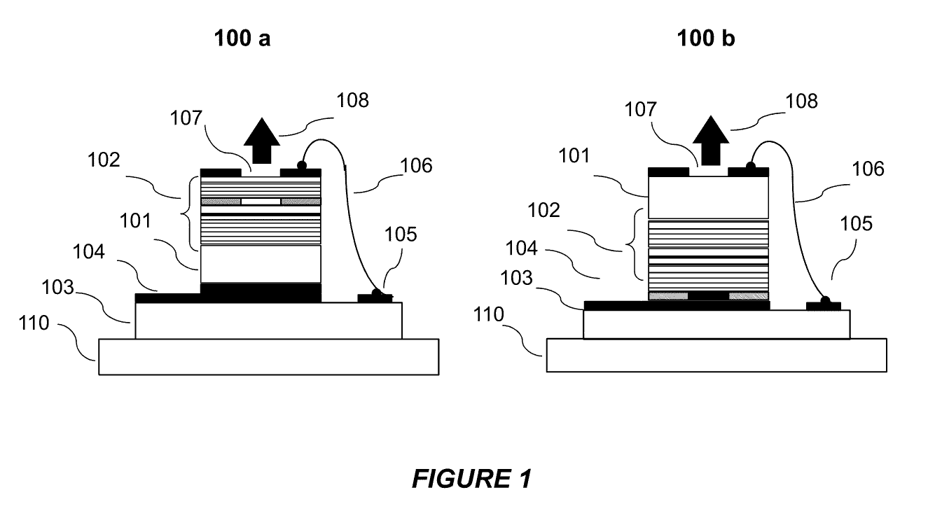

A laser illuminator may be configured using a single high power VCSEL. In one embodiment, an optical module is configured using a single VCSEL as shown in FIG. 1. Principles illustrated through this exemplary embodiment may be used for designing more complex optical modules. Referring to FIG. 1, there it shows schematic views of a single VCSEL device configured in top and bottom emission modes 100a and 100b, respectively, in an optical module. Unless otherwise stated, identical or equivalent parts in both the schematic views are labeled with same reference numerals and will be described at the same time.

Referring to schematic views 100a and 100b, a single VCSEL device 102 constructed on a substrate 101 is disposed on a submount 103 having a set of bonding pads labeled as 104 and 105, respectively located on one surface of the submount. The bonding pads 104 and 105 although located on the same surface of the submount, are electrically isolated. While only one set of bonding pads are shown for illustrative purposes, the submount may include more than one set of bonding pads to connect more VCSELs or for connecting optional peripheral devices for example, a current driver, a power monitor, a control device, etc.

A first electrode (or a first terminal) of the VCSEL is directly bonded to a first bonding pad 104 located on the submount, and a second electrode (or a second terminal) of the VCSEL is wire bonded (106) to the other bonding pad 105. Those skilled in the art will recognize that the designations the first and second electrodes as described here, is merely illustrative and not to be construed as limiting. There are other configurations to connect a two terminal planar device to bonding pads that are well known in the art and are equally applicable for this purpose.

In the configuration shown in 100a, the emission window 107 is located on a top surface of the VCSEL device (hence top emission) opposite to the substrate end whereas, in the device shown in 100b the emission window 107 is located on a substrate surface that is opposite to the surface used to construct the VCSEL. Accordingly, the device shown in 100b is mounted upside down such that the emission window 107 is located on the substrate 101 and light 108 is emitted out from the substrate end (hence bottom emission).

For the ease of description, the VCSEL terminal bonded to the submount will be referred as the bonding surface whereas the light emitting surface will be referred as the emitting surface. It must be noted that the emission window is always on the top end (relative to the page in this example) such that emission 108 from the VCSEL in either case is always in the same direction (pointing up in this example). The definitions of emitting surface, bonding surface and the direction of emission shown in the example is merely illustrative to explain the principles, and is not intended to be limiting.

One important aspect of the invention is that the submount 103 comprises of a material having high thermal conductivity (hence thermal submount) such that the VCSEL bonded to the bonding pad is in good thermal contact with the submount. It is important that the VCSEL electrode directly in contact with the submount has a large surface area for rapid heat dissipation from the VCSEL via the submount. The materials that may be used to construct the submount include but are not limited to, ceramic, metal embedded plastic, diamond, Beryllium Oxide (BeO), Aluminum Nitride (AlN), and other materials known to exhibit high thermal conductivity.

In one variation of the embodiment described above, a high speed electronic circuit for example, an integrated circuit or an electronic chip (electronic module hereinafter) is optionally bonded adjacent to the VCSEL on the same side of the submount. The electronic module includes at least one high speed current driver circuit and may include additional circuits for control and monitoring purposes. The electronic module is bonded to the thermal submount using flip-chip bonding or conventional surface bonding. Electrical connection between the optical module and the electronic module are made using a wide range of methods for example, a high speed transmission line, a wire or wide ribbon bonding, etc. that are already known in the art and will not be described in detail.

For effective heat dissipation from the VCSEL, substrate (101) thickness may be reduced or in some instances, the substrate is completely removed after the VCSEL is constructed. In some other instances the submount may be thinned to a very small thickness to a few tens of microns. It can be appreciated that in order to ensure good thermal contact between the VCSEL and the submount, the methods just described may also be applied in a suitable combination. For efficient heat dissipation, the submount is further placed in good thermal contact with a heat sink 110. Alternatively, the submount may be bonded to a PCB (not shown) including high speed transmission lines and one or more electronic circuits for example, a high speed current driver circuit for connecting the VCSEL. The PCB may optionally include a heat sink and the submount is bonded directly to the heat sink on the PCB.

### VCSEL Array Module:

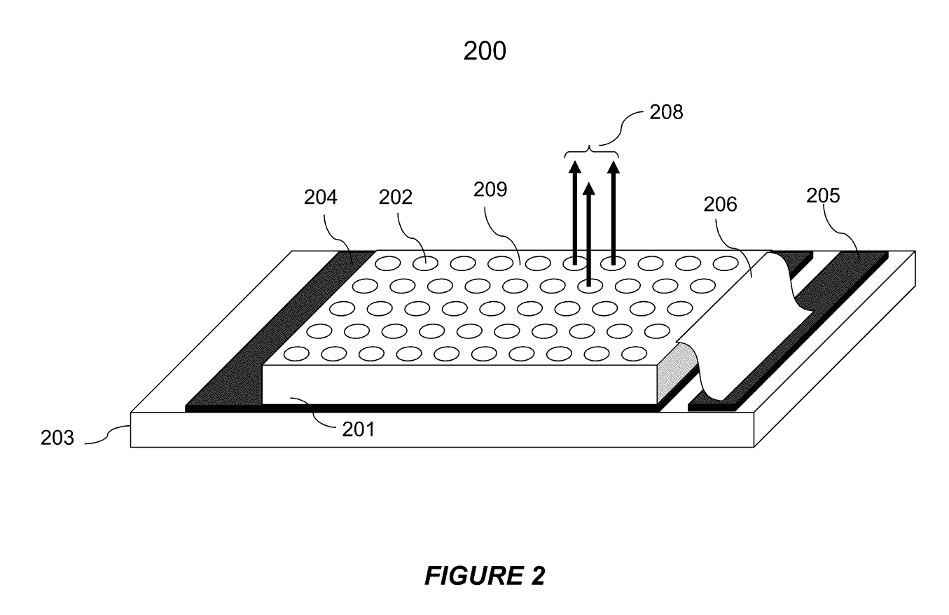

For configuring a high power illuminator an optical module can be configured using a VCSEL array instead of a single high power VCSEL. One embodiment of the invention shown in FIG. 2 is configured as a sub-assembly with a VCSEL array disposed on a thermal submount. More specially, a two dimensional array 209 comprising a plurality of VCSELs 202 (only one is labeled for clarity) is constructed on a common substrate 201. First electrode of each VCSEL is connected together to a common first terminal of the array which in this example is located underside of the substrate 201. Second electrode of each VCSEL is connected together (top surface of the array 209) to a common second terminal of the array. As mentioned earlier, the substrate thickness may be reduced for good thermal contact with the submount.

Accordingly, the underside of the substrate of the VCSEL array which is the common first electrode in this example will be referred as the bonding surface and the top surface of the array will be referred as the emitting surface of the array. The common substrate, is bonded to a large area bonding pad 204 located on the submount 203 to ensure good thermal contact between the VCSEL array and the thermal submount. Multiple wire bonds or a common wide bonding ribbon 206, provides a very low inductance connection to a common second electrode located on the emitting surface, to a second large area bonding pad 205 also located on the common submount. The bonding pads 204 and 205 although located on the same surface of the submount, are electrically isolated. As mentioned earlier in reference with FIG. 1, the thermal submount may include more than one set of bonding pads for co-locating other VCSEL arrays or one or more electronic modules.

The plurality of VCSELs in this example may be top emission or bottom emission type (100a and 100b, respectively in FIG. 1), as long as they are mounted to emit in the same direction (upward in this example) as shown by a representative set of arrows 208 for clarity. In the above example, common electrode connections to all VCSELs allows a common drive current to operate all the VCSELs together thereby, facilitating all the VCSELs to emit together in the same direction, resulting in high output power. The submount is further bonded on a heat sink (not shown in FIG. 2) to facilitate efficient heat dissipation from the VCSEL array.

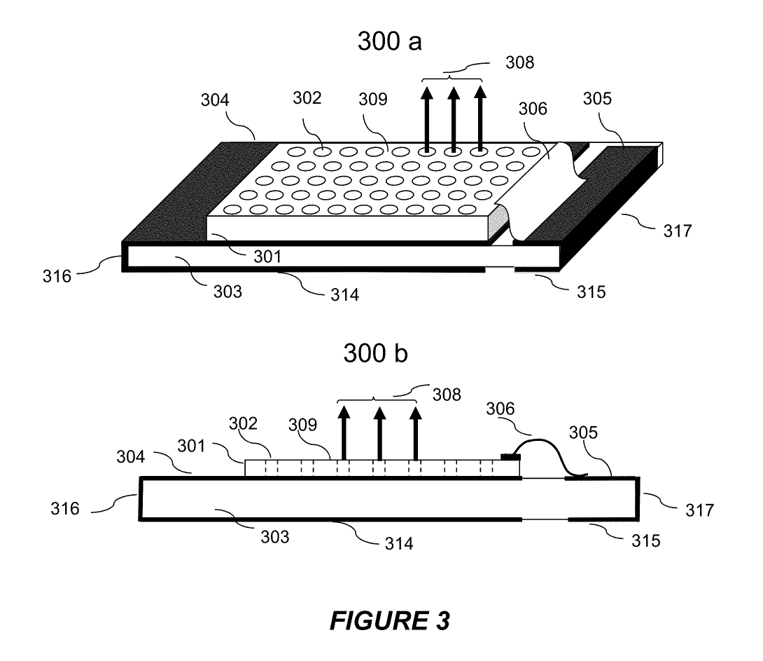

In FIG. 3 is shown a plan view 300a and a corresponding cross-section view 300b, respectively, of another embodiment of an optical module. Identical parts in the two views are labeled with same reference numerals for ease of description. The device shown in 300a (and 300b) is similar to the module shown in FIG. 2 in most respects. More specifically, a two dimensional array 309 comprising a plurality of VCSELs 302 (only one is labeled for clarity) is constructed on a common substrate 301. As mentioned earlier in reference with the module shown in FIG. 2, the plurality of VCSELs in this embodiment also may be top emission or bottom emission type (shown in 100a and 100b, respectively in FIG. 1), as long as they are mounted to emit in the same direction (upward in this example) as shown by a representative set of arrows 308 for clarity.

First electrode of each VCSEL (located underside of the substrate 301 in this example) is connected together to a common first terminal of the array. Second electrode of each VCSEL is connected together (top surface of the array 309) to a common second terminal of the array. As mentioned earlier, the substrate of the array is the bonding surface and the surface of the array is the emitting surface in this example as well. The common substrate, also the common first terminal of the array in this example, is bonded to a bonding pad 304 on a submount 303 having high thermal conductivity such that the heat generated in the VCSEL array is rapidly spread away and dissipated. Multiple wire bonds or a common wide bonding ribbon 306 provides a very low inductance connection to the common second terminal from the VCSEL array emitting surface to a second bonding pad 305 located on the common submount.

The bonding pads 304 and 305 although located on the same surface of the common submount, are electrically isolated. In this embodiment the bonding pads 304 and 305 are wrapped around the respective edges 316 and 317 of the submount 303, and connected to corresponding set of large area bonding pads 314 and 315 on an opposing surface under the submount such that the VCSEL array is in effective thermal contact with the heat sink (not shown in FIG. 3) on which the submount is bonded. This aspect is more clearly seen in the cross-section view 300b. In this embodiment, electrical connections to the VCSEL array is made on the bottom side of the thermal submount for surface mounting the array. For example, the large area bonding pads may be solder bonded to correspondingly designed connector pads on a PCB. Common electrode connections to all VCSELs allows operating the devices together using a common drive current thereby, facilitating all the VCSELs to emit simultaneously to generate high output power. In this embodiment the VCSEL array is electrically connected via the large area bonding pads 314 and 315 to corresponding pads on a PCB for example, to a high speed current driver circuit.

In the exemplary embodiment described above, only one set of bonding pads 304 and 305 are shown which are common between all the VCSELs in the array. It practice,

many bonding pads are co-located on the same surface of the submount. For some applications it is advantageous to connect different sections of the VCSEL array to different drive current circuits so as to operate them in a programmable fashion. Different sections of the VCSEL array may be connected to separate bonding pads on the same thermal submount which are individually wrapped around the respective edges of the thermal submount and connected to a corresponding pad on the underside of the thermal submount.

As mentioned earlier, the thermal submount is placed on a heat sink (not shown in FIG. 3) for efficient heat dissipation. In this embodiment the thermal submount having large area bonding pads underneath, placed on a heat sink or on a heat sink integrated in a PCB results in very low thermal resistance path between the VCSEL array and the heat sink. At the same time the parasitic elements and in particular the inductive impedance of the electrical path is reduced due to large area contact pads, which is a definite advantage for high speed pulse operation of the VCSEL array.

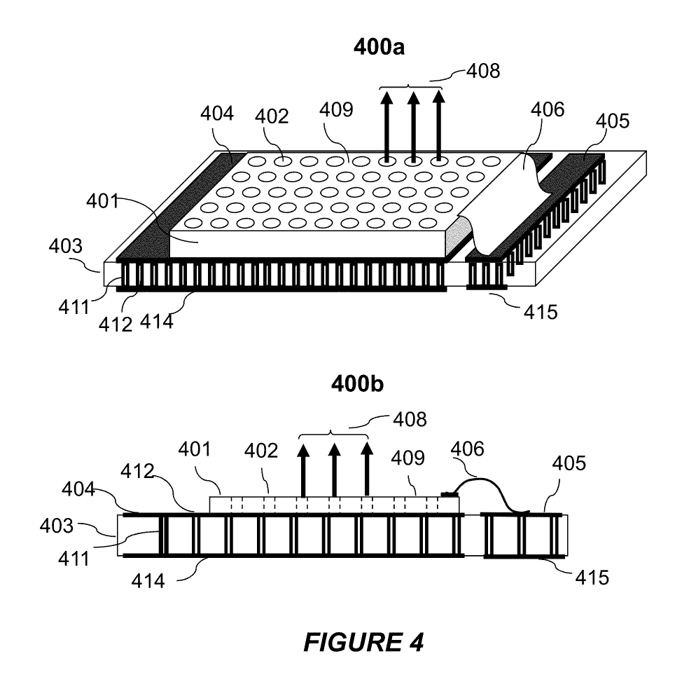

In another embodiment shown in FIG. 4, an optical module is configured using a submount that is different from the thermal submount described in reference with FIG. 3. The module shown in a plan view 400a and a corresponding cross-section view 400b, respectively, is similar to the module described in reference with FIGS. 2 and 3. More specifically, a VCSEL array 409 including a plurality of VCSELs 402 (only one is labeled for clarity) disposed on a common substrate 401, is bonded to a bonding pad 404 located on one surface of a submount 403 such that, one electrode of the VCSEL array (located underside of the array) is in electrical contact with the bonding pad 404. A second electrode located at the top emitting surface of the VCSEL array is wire or ribbon bonded to a second bonding pad 405 located on the same surface of the submount 403 and electrically isolated from the bonding pad 404. The VCSEL array emits parallel beams of light shown by a representative set of arrows 408.

Similar to the embodiment shown in FIGS. 2 and 3, the submount 403 shown in FIG. 4 may be constructed using a high thermal conductivity material. However, in this embodiment, it is not necessary to have a high thermal conductivity material for the submount for dissipating heat away from the VCSEL array. Instead, the submount in this embodiment further includes a plurality of via holes (sometimes also referred to as thru holes) 411 (only one shown from a side view). This aspect of the submount design is more clearly shown in the cross-section view 400b where

identical parts from the view 400a are labeled with the same reference numerals. Individual via holes 412 (only one shown from the top for clarity) are coated or filled with an electrically as well as thermally conducting material to connect the bonding pads 404 and 405 to corresponding set of large area bonding pads 414 and 415, respectively, located on the underside of the submount.

Materials that may be used to coat or fill the via holes include but are not limited to, metals such as copper, silver or gold that exhibit high electrical and thermal conductivity such that the heat generated in the VCSELs is rapidly dissipated to a heat sink (not shown in FIG. 4). As mentioned earlier in reference with the embodiments described in reference with FIGS. 2 and 3, the submount may be placed on a heat sink and/or on a PCB for electrically connecting the VCSEL array to a high speed current driving circuit. In addition to higher thermal conductivity, the plurality of via holes also provide very low inductance electrical contact between the bonding pads 404 and 405 to the respective large area contact pads 414 and 415 and to a high current driver circuit on the PCB.

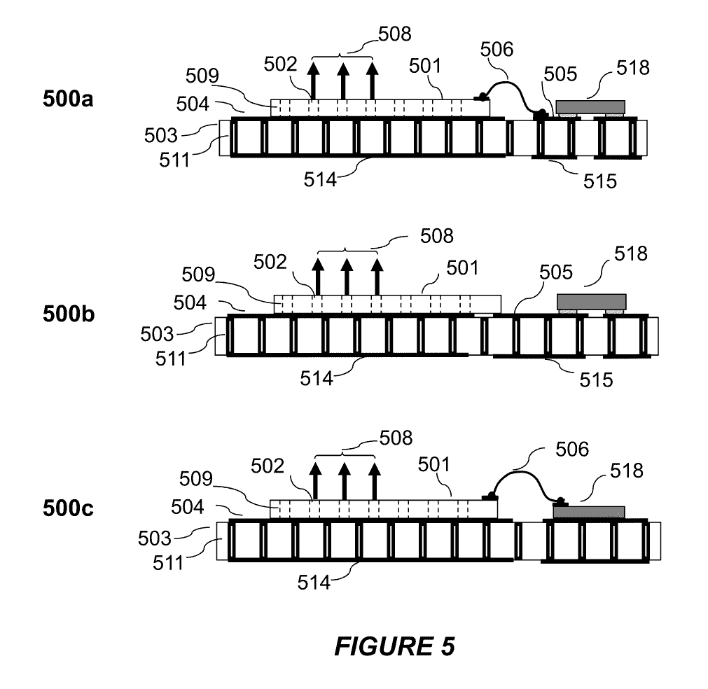

In one embodiment, a high speed optical module is configured using a VCSEL array and an electronic circuit for example, an integrated circuit or an electronic chip (electronic module hereinafter) is optionally bonded to the same thermal submount as shown in FIG. 5. The VCSEL array and the thermal submount are similar to the ones shown in FIG. 4 where identical or equivalent parts in FIGS. 4 and 5 are labeled with same reference numerals. For a more detail description, reference is made to the earlier description associated with FIG. 4. One terminal of the VCSEL array is bonded to a bonding pad 504 on the thermal submount 503. The electronic module including at least one current driver circuit and optional additional circuits for control and monitoring purposes is bonded to the thermal submount using either flip-chip bonding or conventional surface bonding as shown respectively in schematic views 500a, 500b and 500c.

In the schematic view 500a the VCSEL array 509 is electrically connected using a wire or ribbon bonding 506 to the electronic module on the common bonding pad 505. An alternative way of electrically connecting the VCSEL array to the electronic module is shown in the schematic 500b. In this method the electronic module is mounted in a flip chip configuration on the same surface of the submount on which the VCSEL array is bonded. The electrical connection between the VCSEL array and for example a current driver circuit is made using a transmission line 505. The transmission line 505 may be further connected to active or passive impedance matching components. More specifically, a via hole (not shown) located on the VCSEL array's top emitting surface and the substrate 501 provides a conducting path between the terminal of the VCSEL array and the transmission line 505 shared with the electronic module 518. In the schematic view 500c, the electronic module 518 is bonded on the substrate side to a bonding pad on the thermal submount and is electrically connected to the terminal of the VCSEL array using a wire or wide ribbon bonding 506.

It will be apparent to those skilled in the art that while these exemplary embodiments show only one set of bonding pads and one set of VCSEL array and electronic module on the thermal submount for clarity, each thermal submount may include many more bonding pads to incorporate more VCSEL arrays and electronic modules for configuring larger optical modules, for example. One advantage of including the electronic module on the same submount is to facilitate high speed operation of the VCSEL array by reducing the parasitic elements for example, the inductive impedance of the current drive circuit.

While this aspect of the invention is explained using a submount with plurality of via holes, the principles are equally applicable to the wrap around submount design described earlier in reference with FIG. 3. Those skilled in tha art will recognize that different bonding pads co-located on the submount may be wrapped around respective edges of the submount and connected to a corresponding set of large area bonding pads on an opposing surface under the submount so as to connect different VCSEL arrays and/or electronic modules.

### Beam Shaping and Emission Patterns:

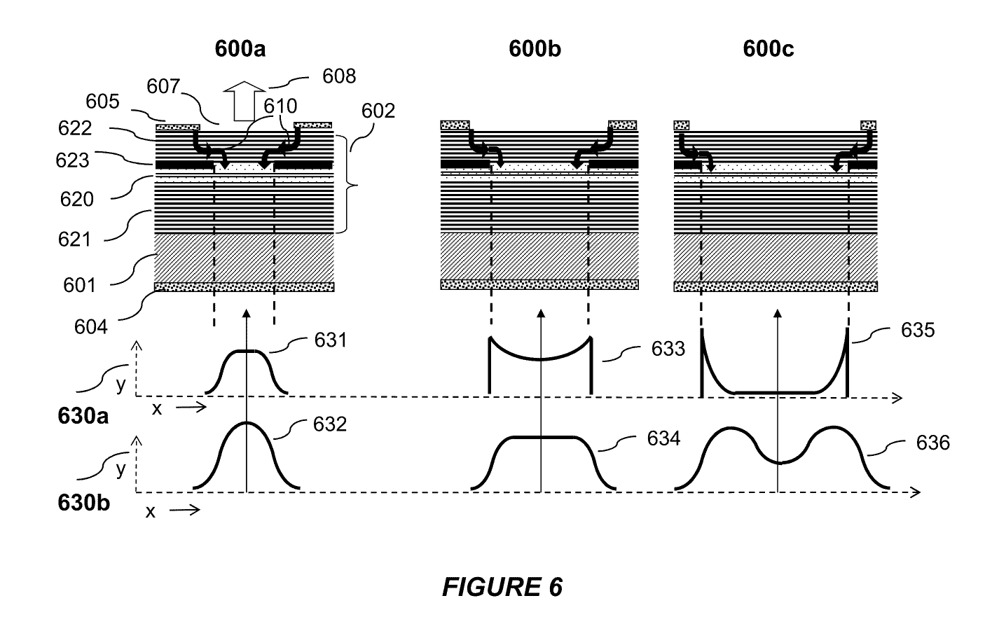

The emitted radiation pattern from a VCSEL is typically a circular beam with a relatively small divergence angle. In some applications there may be a need for a beam with different shape and/or characteristics. FIG. 6 shows different output beam shapes corresponding to different VCSEL structures. The beam shapes may be altered by incorporating different structural changes to the basic VCSEL structure shown in FIG. 1. Referring back to FIG. 6, there it shows VCSEL structures 600a, 600b and 600c together radial distribution of gain in graph 630a and radial distribution of far-field beam pattern in graph 630b respectively. The VCSEL shown therein is a top emission structure (similar to 100a in FIG. 1); only one device is labeled for clarity. The VCSEL 602 disposed on a substrate 601, comprises an active region 620 bounded by lower and upper Distributed Bragg Reflectors (DBR) 621 and 622, respectively. An aperture 623 disposed between the active region and the upper DBR 622 defines the diameter of the region where current is injected. An electrode 604 is disposed on the bottom surface of the substrate whereas current is injected from the top electrode 605 disposed as a ring around the emission window 607 in exemplary VCSEL structures in 600a, 600b and 600c. The VCSEL structures shown here are similar except for the diameters of the aperture (623) and the emission window (607).

In a typical selectively oxidized VCSEL structure, the oxide aperture (623) ‘funnels’ the injected current 610 into the active region 620 as is well known in the art. As shown in 600a, for small oxide aperture with a diameter comparable to the thickness of the top DBR 622, the current is injected uniformly into the active region, generating a uniform carrier profile 631, and in turn a uniform gain profile. The current funneling can be accomplished with implanted structure as well in which proton implantation is done to increase the resistivity at the edges of the device creating an aperture as is done with the oxide so that the current funnels through the center. This is also well known in the art. It must be noted that most of the gain is concentrated in the center of the aperture. This favors optical modes having energy concentrated in the center of the aperture. In the far-field, the output beam predominantly has a ‘Gaussian’ shape 632 with a relatively small divergence (even though it may not necessarily be single-mode).

As the oxide aperture increases in diameter as shown in structures VCSEL 600b and 600c, the current tends to be injected into the active region more at the periphery of the oxide aperture. This gives rise to non-uniform gain profile 633 and 635, respectively for structures 600b and 600c with noticeable gain depletion in the center of the active region. Consequently, optical energy is concentrated at the periphery. The far-field output beam profile shifts from a predominantly Gaussian shape to a quasi ‘flat-top’ shape as shown in 634 and in the extreme case, to a ‘donut’ shape profile 636 with increasing beam divergence. It can be appreciated that a VCSEL structure may be designed to result in a desired far-field output beam profile with a specific beam divergence.

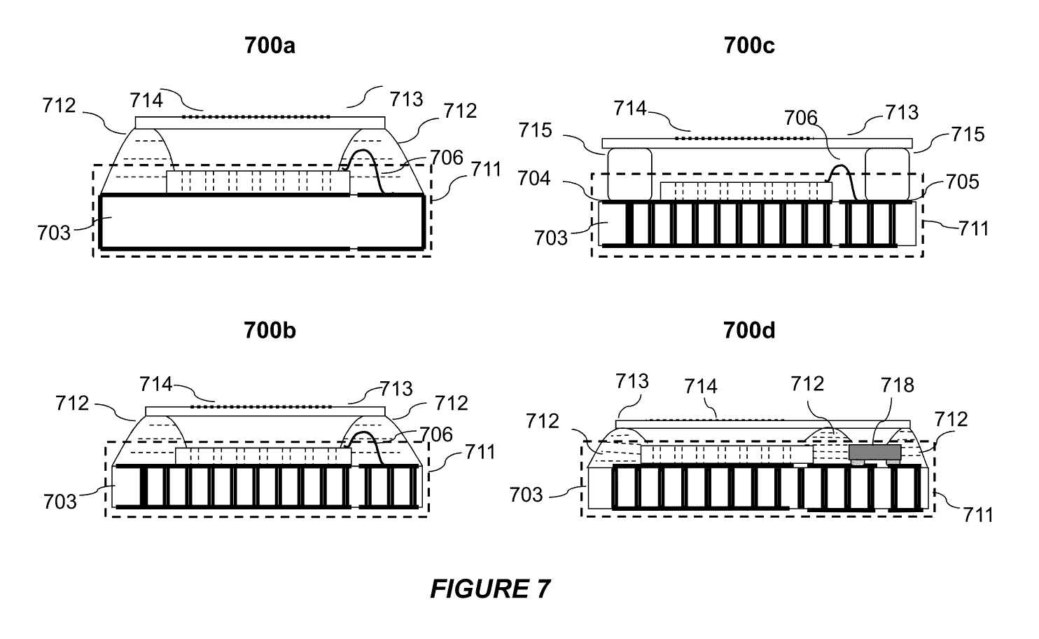

Alternatively, output beam profile may be reshaped or modified to obtain a desired emission pattern by placing one or more optical components placed in front of the VCSEL output beam. As an example, the optical component may just be a transparent window or may further include one or more beam shaping elements. Referring to FIG. 7, there it shows VCSEL sub-assemblies 700a, 700b and 700c including external optical components. Identical parts in the separate views are labeled with same reference numerals and will be described in general. More specifically, parts enclosed in a dashed box 711 collectively represent a VCSEL array sub-assembly described earlier in reference with FIGS. 2, 3, 4, and 5 and will not be described again. In configurations 700a and 700b a ring of bonding material 712 such as solder or epoxy, is placed on the submount around the edge of the VCSEL array and an optical component 713 is attached to the bonding ring.

As an example, when additional beam shaping is not required, the optical component is just a transparent window. The optical component is aligned at a pre-determined height above the VCSEL sub-assembly 711 so as to encapsulate the electrical wire or ribbon connector 706 located on the top emitting surface of the VCSEL array for additional mechanical support. Furthermore, the encapsulation material hermetically or non-hermetically seals the VCSEL array together with the optical component. When beam shaping is required, the optical component may further include one or more beam shaping elements or arrays of said elements, collectively shown as 714 in FIG. 7.

The beam shaping elements 714 may be mounted or formed on the optical component 713. The optical component including the beam shaping elements is placed at a predetermined height above the VCSEL sub-assembly 711 and laterally aligned with the VCSEL array, such that the beams emitted from the VCSEL array pass through the optical elements 714 at a correct distance required for the desired beam shaping operation. Selection of the optical elements is predetermined according to the beam shaping or emission pattern requirement desired for a particular application. Beam shaping elements may include but are not limited to, lenses, micro-lenses, apertures, beam diffusers, etc. or arrays of one or more of these elements. In case different parts of the array need different type of beam shaping, different beam shapers can be added in a single layer or multiple levels of beam shapers can be added by stacking them on top of each other. Furthermore, the beam shaping elements, such as micro-lenses or diffusers may be integrated with the VCSELs by fabricating them on top of VCSELs optical component or may be external to the VCSELs or to the optical component.

In an alternative embodiment shown as 700c, the optical component 713 is attached to the VCSEL array sub-assembly using solder bump technology. The optical component 713 can be mounted by using epoxy bumps as shown in 712 all around the VCSEL array. The optical component may include one or more beam shaping elements 714 or arrays of said elements on one surface. In this embodiment the optical component 713 also includes ready to solder metal pads 715 deposited on the surface that does not include the beam shaping elements. The thickness of the solder metal pads is determined by the height where optical elements have to be placed for the required beam shaping operation. The optical component is laterally aligned with the bonding pads 704 and 705 on the submount 703 such that emission from the VCSEL array passes through the beam shaping elements at a distance required for the desired beam shaping operation. The solder or epoxy around the VCSEL array and the attached optical component also provides sealing for the VCSEL array to protect it from external elements.

One embodiment of an optical module including a high speed electronic module is shown in a schematic view 700d. In this embodiment the dashed box 711 represents a high speed optical module similar to one shown in FIG. 500b. In this example, a bonding material 712 for example, a solder or an epoxy, is placed on the submount around the VCSEL array as well as the electronic module 718, with an optical component 713 to encapsulate the entire optical module. The optical component may just be a transparent window or may include optional additional optical elements 714 or arrays of said elements, when beam shaping is required. The solder or epoxy around the VCSEL array and the attached optical component also provides sealing for the VCSEL array to protect it from external elements. While this embodiment is described in reference with the optical module 500b shown in FIG. 5, the description is equally pertinent for other optical modules 500a and 500c shown in FIG. 5 as well.

### High Speed Optical Module:

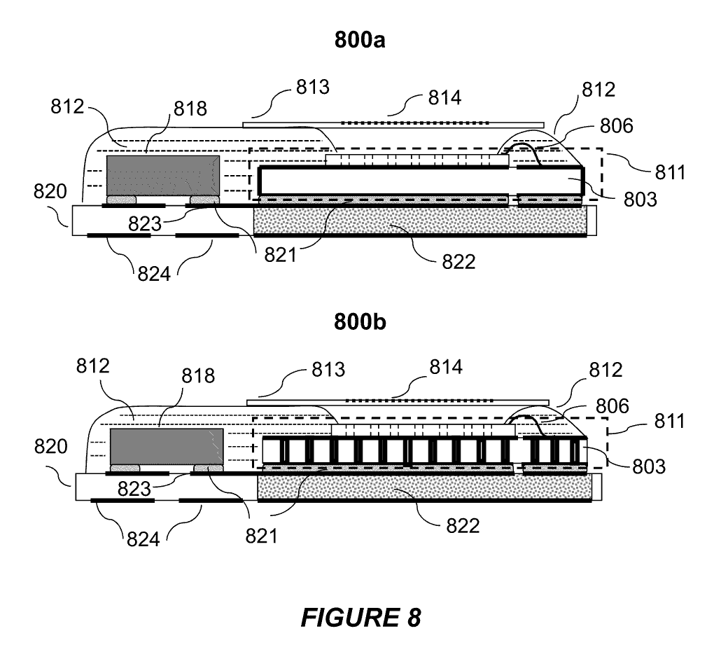

A VCSEL array together with the beam shaping optical elements as described earlier, may be used to configure a high speed optical module shown in FIG. 8. Exemplary

embodiments of a high speed module shown in schematic views 800a and 800b are similar in principle to the high speed optical module described in reference with FIG. 5. Common features of exemplary high speed optical modules 800a and 800b are labeled with similar reference numerals and will be described together for a clear understanding. More specifically, a typical high speed module has an optical module 811 represented by a dashed box and an electronic module 818. The high speed optical modules shown in 800a and 800b are substantially similar in almost all respects, to optical modules described earlier in reference with FIGS. 3 and 4, respectively, and include a VCSEL array bonded on a thermal submount 803. The submount in 800a is different from the submount in 800b in that the latter includes a plurality of via holes described earlier in reference with FIGS. 4 and 5.

In addition to the optical module, the exemplary high speed module includes a high speed electronic module 818 including at least one high speed current driving device. The optical and electronic modules are surface mounted on a PCB 820 using a thermally conductive binding medium 821 such as a solder, an epoxy and other materials that are well known in the art for surface bonding electronic chips to a PCB in a high speed electronic circuits. The PCB further includes one or more high speed transmission lines 823 (only one labeled) on one surface and a plurality of ground planes 824 (only a few shown) on an opposing surface under the PCB. The electronic module is electrically connected to the optical module using high speed transmission line 823 for example, to drive, modulate and control the VCSEL arrays at high speed. The PCB may optionally include a heat sink region 822 to which the optical module is directly bonded for efficient heat dissipation.

The optical module in the exemplary high speed sub-assembly includes an optical component 813 including one or more beam shaping elements 814 or arrays of such elements, described earlier in reference with FIG. 7. The optical component is attached to the sub-assembly using a bonding material 812 such as a solder or epoxy, disposed on the optical module submount 803 as well as on the PCB such that the optical component is aligned to the VCSEL array on the optical module and the electronic module is encapsulated on the PCB. It can be appreciated that the arrangement for the high speed sub-assembly described here is only exemplary and other arrangements for assembling the optical module with the electronic module that may occur to those skilled in the art are within the purview of this invention.

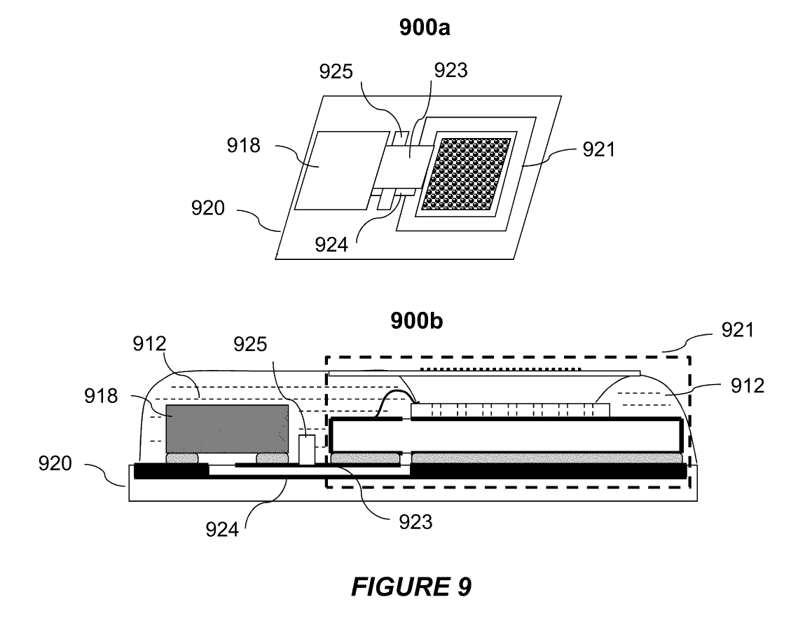

FIG. 9 shows an exemplary arrangement for connecting an optical module to an electronic module on a PCB using high speed transmission lines. More specifically, the plan view 900a and a corresponding cross-section view 900b, respectively, show a PCB 920 including an optical module 921 (shown as a dashed box in 900b) and an electronic module 918 connected by a high speed transmission line 923 and a ground plane 924 on either side (only one side is labeled for clarity). In addition, active or passive impedance matching elements 925 (only one is labeled for clarity) are disposed on either side of the transmission line. Those skilled in the art will be able to appreciate that the transmission line in this example may be stripline micro stripline or co-planar type, and are well known in the art. Although not labeled explicitly in the figure, the optical module as shown in this embodiment includes the beam shaping elements that are attached to the module using a bonding material as described earlier in reference with FIG. 8.

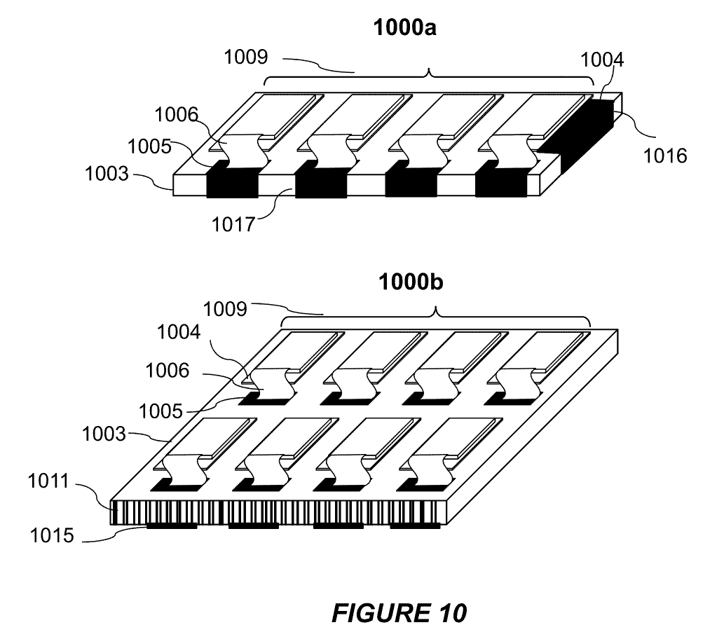

Although the optical module used to configure the embodiments shown in FIGS. 9 and 10 uses the arrangement shown as 700a in FIG. 7, these embodiments will work equally well with the arrangements shown as 700b, 700c or 700d in FIG. 7 where the thermal submount includes a plurality of via holes. In fact, embodiments using different combinations and sub-combinations of these basic modules will be apparent to those skilled in the art and different embodiments can be constructed within a broad framework of the description presented in earlier sections. One advantage of including high speed transmission line on the same PCB platform together with the optical and electronic modules is to reduce parasitic circuit elements and particularly the inductance, for high speed operation of the VCSEL array. In addition, other electronic components for example, pre-fabricated programmable components for high speed control operations may optionally be included on the same PCB platform.

While all the embodiments described earlier are shown with a single VCSEL array. In practice, a plurality of VCSEL arrays may be co-located on the same submount. Exemplary configurations are shown in FIG. 10 where schematic views of a one dimensional and a two dimensional array of VCSEL arrays are 1000a and 100b, respectively are shown to be co-located on the same submount 1003. More specifically, 1000a shows a 1×N array of VCSEL arrays (collectively labeled as 1009) on a common submount. The submount includes a plurality of bonding pads 1004 and 1005 wrapped around a nearest edge 1016 and 1017, respectively, to connect to a corresponding set of large area bonding pads located on the opposing surface under the submount (not shown in FIG. 10). This embodiment may be adapted to construct a 2×N array. Another embodiment including a 2×N array of VCSEL arrays is shown in 1000b on a submount having a plurality of via holes 1011 to connect each bonding pad on a surface of the submount 1003 (only 1004 and 1005 are shown for clarity) to a corresponding set of large area bonding pads (only one 1015, is shown for clarity) on an opposing surface under the submount 1003. The embodiment shown in 1000b is more suitable for adapting to M×N arrays.

Each VCSEL array may be connected separately using ribbon bonding (1006), or collectively to one or more current driver circuit. Furthermore, VCSELs in different arrays may have different current confining aperture structure(s) to facilitate different emission patterns. Those skilled in the art will be able to recognize that VCSELs in different arrays may be connected in a modular fashion. For example, all the arrays on the submount may be connected together or separately, may be operated or programmed to operate in desired mode and/or desired combinations thereby, providing a large number of possibilities for generating different illumination power and emission patterns.

### Illuminator System:

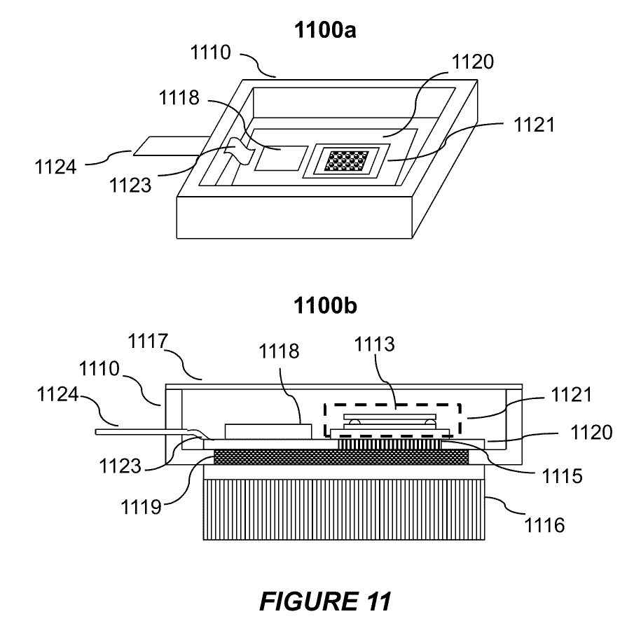

A combination of different modules described earlier may be used to configure a high speed, high power illuminator system shown in FIG. 11. A plan view 1100a shows an overall picture of an illuminator system. Details of the illuminator system will be better understood in reference with a corresponding cross-section view 1100b. Similar elements in both views are labeled with same reference numerals to avoid repetitive description. More specifically, the illuminator system shown in 1100a and 1100b comprises an optical module 1121 directly bonded to a PCB 1120 together with a high speed electronic module 1118. The electronic module includes at least one current driving device to supply drive current to the optical module. The electronic module includes other devices for providing one or more control functionalities to the optical module. In this embodiment, the electronic module may be addressed remotely through an external controller (not shown) using a high speed link comprising a transmission line 1123 (stripline or microstrip) located on the PCB, and an external connector 1124 located on the housing 1110 of the illuminator.

The optical module comprises a VCSEL array disposed on a thermal submount described earlier in reference with FIGS. 2, 3, 4, 5, 7 and 8. Each optical module may include one or more VCSEL arrays. Furthermore, the optical module may include one or more beam shaping elements or arrays of said elements similar to those described in reference with FIGS. 7, 8, 9 and 10. The optical module is bonded on a bonding pad 1115 on the PCB using a large area bonding pad located on the underside of the submount as has been described earlier in reference with FIGS. 3, 4 and 5. The bonding pad on the submount may be placed directly on a heat sink region optionally included in the PCB, such that the submount under the VCSEL array is bonded to the heat sink region of the PCB so as to facilitate direct thermal contact between the VCSEL array and the heat sink region. The PCB in turn is bonded to the base 1119 of an enclosure 1110, thereby providing an efficient thermal conducting path between the VCSEL arrays and an external heat sink 1116 of the illuminator enclosure.

A transparent cover 1117 is provided on an opposing end from the base of the enclosure, to hermetical or non-hermetical sealing of the enclosure. Instead of including the beam shaping elements on the optical module similar to that described in reference with FIG. 7, the transparent cover may alternatively be used to provide beam shaping elements. The distance between the optical module and the transparent cover is accordingly adjusted so as to achieve a desired beam shape from the optical module. As mentioned earlier, the illuminator may include more than one VCSEL array for high power and/or large area illumination. The multiple VCSEL arrays can be connected together electrically in series or in parallel for them to work in a synchronous fashion.

For clarity and simplicity of discussion, the exemplary modules are described using a single VCSEL or an array of VCSELs constructed on a single substrate. Those skilled in the art will be able to appreciate that in practice, several individual VCSELs or arrays may be constructed on a single large area substrate. Each device or array on a substrate may be connected to separate current drivers or connected to a common current driver, depending upon the required output power. While the exemplary embodiments described above use a regular two-dimensional array of VCSELs constructed on the same substrate, any array of VCSELs regular or irregular, may be created by arranging single high power VCSELs in desired patterns, for example, a linear or one-dimensional array, an irregular two dimensional array etc.

Similarly, each module described earlier in reference with FIGS. 2, 3, 4 and 5 is described to be disposed on an individual thermal submount. In practice, more than one module may be disposed on a single thermal submount. Larger two dimensional VCSEL arrays may be created by arranging one dimensional arrays or smaller two-dimensional arrays connected together on a common bonding pad or on separate bonding pads on the thermal submount. Advantageously, small size of VCSELs facilitates closely packed arrays thereby, resulting in a very uniform and speckle free illumination pattern.

Furthermore, different arrays may be programmed to be operated separately or collectively using one or more driving current circuits depending upon the output power requirement. Each array may be programmed for synchronous, asynchronous, continuous, pulsed or sequential operation. Packaging the optical and electronic module on the same PCB using high speed transmission lines allows pulse operation of the VCSEL array at high speed (of the order of Gb/s) and can be modulated using external controller. Furthermore, different sections of the VCSEL array may be configured to be operated or modulated at different rates.

The description provided here is intended to cover a broad framework of constructing and operating high speed and high power laser illuminators using VCSEL arrays in a modular fashion. Those skilled in the art will be able to appreciate that the modular characteristics of configuring and programming the VCSEL arrays offers a wide range of choices in operating speed and control, for generating different illumination patterns required for different types of applications, a few of which are mentioned earlier in the background art section.

Although the invention has been described in detail with reference to the preferred embodiments, a complete framework of the invention is provided in various combinations and sub-combinations of these embodiments. Applications of the principles embodied in these descriptions would result in many design choices that will occur to those skilled in the art and may lead to large number of different devices, are implicitly covered within this broad framework. All such variations and modifications of the present invention are intended to be covered in appended claims.

1-8. (canceled)

9. An optical illuminator module comprising:
a) a plurality of Vertical Cavity Surface Emitting Lasers (VCSELs) arranged in an array, said array having a light emitting surface and an opposing bonding surface, a first terminal of each VCSEL being electrically connected to a first terminal of the array and a second terminal of each VCSEL being electrically connected to a second terminal of the array; and
b) a submount including a plurality of electrically isolated bonding pads on one surface, the first and the second terminal of the being electrically connected to respective bonding pads on the submount, such that the bonding surface of the array is in thermal contact with the submount.

10. The optical illuminator module as in claim 9, wherein the submount comprises of a material having high thermal conductivity.

11. The optical illuminator module as in claim 9, wherein the bonding pads are wrapped around one or more edges of the submount, such that the bonding pads are electrically connected to a corresponding set of bonding pads located on an opposing surface of the submount.

12. The optical illuminator as in claim 9, wherein the submount includes a plurality of via holes such that the bonding pads on the one surface of the submount are in electrical and thermal contact with a corresponding set of bonding pads located on an opposing surface of the submount.

13. The optical illuminator module as in claim 9 further including an electronic module bonded adjacent to the VCSEL on the submount, wherein the electronic module includes at least one current driver circuit electrically connected to the at least one VCSEL.

14. The optical illuminator module as in claim 9, wherein current confining apertures in one or more of the plurality of VCSELs are shaped so as to emit a predetermined emission pattern.

15. The optical illuminator module as in claim 9 further comprising at least one optical component attached to the submount such that the VCSEL array is encapsulated between the submount and the optical component.

16. The optical illuminator module as in claim 9, wherein the submount is bonded to a heat sink or a printed circuit board comprising a heat sink, such that the VCSEL array is in thermal contact with the heat sink via the submount.

17. The optical illuminator module as in claim 9 further comprising one or more additional VCSEL arrays co-located with the VCSEL array on the submount, each additional VCSEL array comprising a light emitting surface and an opposing bonding surface, the first and the second terminals of each additional array being electrically connected to a respective bonding pads on the submount such that the bonding surface of each additional array is in thermal contact with the submount.

18. A high-speed optical illuminator module comprising;
a) an optical module comprising:
1) a plurality of Vertical Cavity Surface Emitting Lasers (VCSELs) arranged in an array, said array having a light emitting surface and an opposing bonding surface, a first terminal of each VCSEL being electrically connected to a first terminal of the array and a second terminal of each VCSEL being electrically connected to a second terminal of the array; and
2) a submount including a plurality of electrically isolated bonding pads located on one surface of the submount, the first and the second terminal of the array being electrically connected to respective bonding pads on the submount, such that the bonding surface of the array is in thermal contact with the submount;
b) an electronic module comprising at least one current driver circuit; and
c) a printed circuit board comprising one or more transmission lines on a first surface of the printed circuit board, the electronic module and the optical module being bonded on respective bonding pads on the first surface of the printed circuit board to electrically connecting the VCSEL array to the at least one current driver circuit.

19. The optical illuminator module as in claim 18, wherein the submount comprises of a material having high thermal conductivity.

20. The optical illuminator module as in claim 18, wherein the bonding pads are wrapped around one or more edges of the submount, such that the bonding pads are connected to a corresponding set of bonding pads located on an opposing surface under the submount.

21. The optical illuminator module as in claim 18, wherein the submount includes a plurality of via holes such that the bonding pads on the one surface of the submount are in electrical and thermal contact with a corresponding set of bonding pads located on an opposing surface of the submount.

22. The optical illuminator module as in claim 18, wherein current confining apertures in one or more of the plurality of VCSELs are shaped so as to emit a predetermined emission pattern.

23. The optical illuminator module as in claim 18 further includes at least one optical component attached to the submount, such that the VCSEL array is encapsulated between the submount and the optical component.

24. The optical illuminator module as in claim 18, wherein the printed circuit board comprising a heat sink positioned such that the optical module bonded on the printed circuit board is in thermal contact with the heat sink via the submount.

25. The optical illuminator module as in claim 18, further comprising a heat sink thermally bonded to the printed circuit board.

26. An optical illuminator system comprising:
a) an optical module, said optical module comprising;
1) a plurality of Vertical Cavity Surface Emitting Lasers (VCSELs) arranged in at least one array, said at least one array having a light emitting surface and an opposing bonding surface, a first terminal of each VCSEL being electrically connected to a first terminal of the at least one array and a second terminal of each VCSEL being electrically connected to a second terminal of the at least one array; and
2) a submount including a plurality of electrically isolated bonding pads on one surface, the first and the second terminal of the at least one array being electrically connected to respective bonding pads on the submount, such that a bonding surface of the at least one array is in thermal contact with the submount;
b) an electronic module comprising at least one current driver circuit;
c) a printed circuit board including at least one transmission line on a first surface of the printed circuit board, the optical and the electrical modules being bonded to the first surface of the printed circuit board, and the optical and the electrical modules being electrically connected through the at least one transmission line; and
d) an enclosure including a base on one end and a transparent region on the opposing end of the base, the printed circuit board being bonded to the base of the enclosure such that the light emitting surface of the optical module faces the transparent region of the enclosure, and said base being disposed on a heat sink that is external to the enclosure such that the printed circuit board is in thermal contact with the heat sink.

27. The optical illuminator system as in claim 26, wherein the submount comprises a material having high thermal conductivity.

28. The optical illuminator system as in claim 26, wherein the bonding pads are wrapped around one or more edges of the submount, such that the bonding pads are electrically connected to a corresponding set of bonding pads located on an opposing surface of the submount.

29. The optical illuminator system as in claim 26, wherein the submount comprises a plurality of via holes such that the bonding pads on the one surface of the submount are in electrical and thermal contact with a corresponding set of bonding pads located on an opposing surface of the submount.

30. The optical illuminator module as in claim 26, wherein current confining apertures in one or more of the plurality of VCSELs are shaped so as to emit a predetermined emission pattern from the VCSEL array.

31. The optical illuminator system as in claim 26 further comprising at least one optical component attached to the submount, such that the VCSEL array is encapsulated between the submount and the optical component.

32. The optical illuminator system as in claim 26, wherein the transparent region of the enclosure further comprises beam shaping elements.

33. The optical illuminator system as in claim 26, wherein the printed circuit board further comprises a heat sink, positioned such that the optical module bonded to the printed circuit board is in thermal contact with the heat sink via the submount.

34. The optical illuminator system as in claim 26 further comprising an external connector located proximate to the enclosure, the external connector being electrically connected to one or more transmission lines on the printed circuit board, such that the electronic and optical modules are operated using an external controller connected to the external connector.

35. An optical illuminator module comprising:
a) a Vertical Cavity Surface Emitting Laser (VCSEL) having a large area terminal and a second terminal; and
b) a submount including a first and second bonding pad that are electrically isolated from each other and positioned on a first surface, the large area terminal of the VCSEL being bonded to the first bonding pad such that the VCSEL is in thermal contact with the submount, the second terminal being electrically connected to the second bonding pad, the first and second bonding pads being electrically connected to a corresponding first and second bonding pad located on a second surface of the submount, which is opposite to the first surface of the submount.

36. The optical illuminator module of claim 35, wherein the submount is bonded to a heat sink such that the VCSEL is in thermal contact with the heat sink.

37. The optical illuminator module of claim 35, wherein the first and second bonding pads on the first surface of the submount are wrapped around one or more edges of the submount, such that the first and second bonding pads on the first surface of the submount are electrically connected to the corresponding first and second bonding pads positioned on the second surface of the submount.

38. The optical illuminator module of claim 37, wherein the submount is bonded to a heat sink such that the VCSEL is in thermal contact with the heat sink.

39. The optical illuminator module of claim 35, wherein the first and second bonding pads on the first surface of the submount are wrapped around one or more sides of the submount, such that the first and second bonding pads on the first surface of the submount are electrically connected to the corresponding first and second bonding pads positioned on the second surface of the submount.

40. The optical illuminator module of claim 39, wherein the submount is bonded to a heat sink such that the VCSEL is in thermal contact with the heat sink.

41. The optical illuminator module of claim 35, wherein the first and second bonding pads positioned on the first surface of the submount are electrically connected to the corresponding first and second bonding pads positioned on the second surface of the submount by first and second via holes.

42. The optical illuminator module of claim 41, wherein the submount is bonded to a heat sink such that the VCSEL is in thermal contact with the heat sink.

43. The optical illuminator module of claim 35, wherein the first and second bonding pads positioned on the first surface of the submount are electrically connected to the corresponding first and second bonding pads positioned on the second surface of the submount by a corresponding plurality of first and a plurality of second via holes.

44. The optical illuminator module of claim 35, wherein the illuminator module is configured to perform at least one of motion recognition, gesture recognition, and three-dimensional sensing.

45. The optical illuminator module of claim 35 further including an electronic module bonded adjacent to the VCSEL on the submount, the electronic module comprising at least one high-speed current driver circuit electrically connected to the at least one VCSEL.

46. The optical illuminator module of claim 35, wherein the VCSEL comprises a current confining aperture defining a shape that achieves a predetermined emission pattern.

47. The optical illuminator module of claim 35 further comprising at least one optical component attached to the submount, such that the VCSEL is encapsulated between the submount and the optical component.

48. The optical illuminator module of claim 47 wherein the optical component comprises one or more beam shaping elements.

49. The optical illuminator module as in claim 15, wherein the optical component comprises one or more beam shaping elements or arrays of said beam shaping elements.

50. The optical illuminator module as in claim 23, wherein the optical component comprising one or more beam shaping elements.

51. The optical illuminator system as in claim 31, wherein the optical component comprises one or more beam shaping elements.
